(19) United States
(12) Patent Application Publication
(10) Pub. No.: US 2026/0143665 A1
(43) Pub. Date: May 21, 2026

(54) SEMICONDUCTOR DEVICE AND METHOD FOR FORMING THE SAME

(71) Applicants: TAIWAN SEMICONDUCTOR MANUFACTURING COMPANY, LTD., Hsinchu (TW); NATIONAL YANG MING CHIAO TUNG UNIVERSITY, Hsinchu City (TW)

(72) Inventors: Hsin-Cheng LIN, Taipei City (TW); Chien-Te TU, Hsinchu City (TW); Chee-Wee LIU, Taipei City (TW)

(73) Assignees: TAIWAN SEMICONDUCTOR MANUFACTURING COMPANY, LTD., Hsinchu (TW); NATIONAL YANG MING CHIAO TUNG UNIVERSITY, Hsinchu City (TW)

(21) Appl. No.: 18/955,405

(22) Filed: Nov. 21, 2024

(51) Int. Cl. H10B 10/00

(52) U.S. Cl. CPC H10B 10/125

(57) ABSTRACT

A semiconductor device includes a substrate having a semiconductor fin, a first transistor over the substrate, and a second transistor vertically above the first transistor. The first transistor includes a first gate structure over the semiconductor fin, in which in a cross-sectional view, the semiconductor fin comprises a channel portion in contact with a bottom surface of the first gate structure, and source/drain portions on opposite sidewalls of the first gate structure. The second transistor includes a semiconductor channel layer above the semiconductor fin, a second gate structure over the semiconductor channel layer, and source/drain epitaxy structures on opposite ends of the semiconductor channel layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

As the semiconductor industry further progresses into technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 16E illustrate a method in various stages of forming a semiconductor device in accordance with some embodiments of the present disclosure.

FIG. 17 is a cross-sectional view of a semiconductor device in accordance with some embodiments of the present disclosure.

FIG. 18 illustrates a circuit diagram of a static random access memory (SRAM) cell, in accordance with some embodiments of the disclosure.

FIG. 19 is a cross-sectional view of a semiconductor device in accordance with some embodiments of the present disclosure.

FIG. 20 is a cross-sectional view of a semiconductor device in accordance with some embodiments of the present disclosure.

FIGS. 21 and 22 are simulation results of semiconductor devices in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

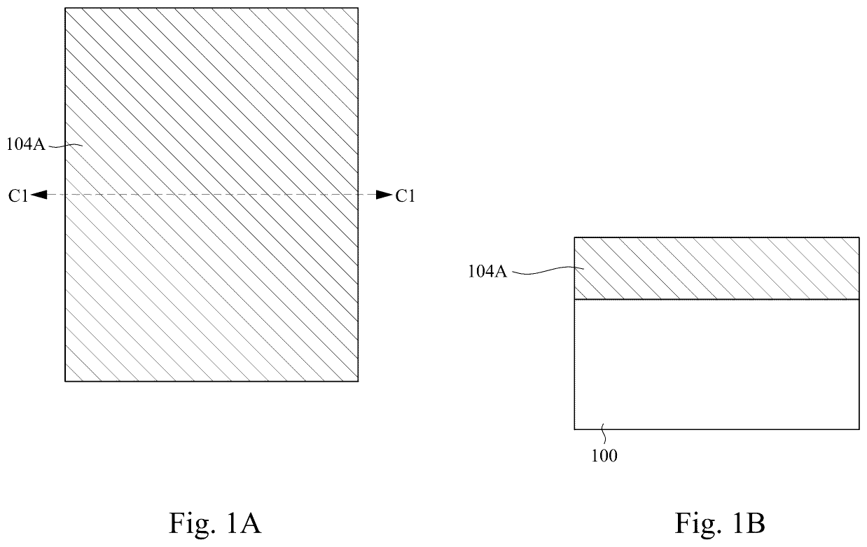

FIGS. 1A to 16E illustrate a method in various stages of forming a semiconductor device in accordance with some embodiments of the present disclosure. Although FIGS. 1A to 16E are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 1A and 1B, in which FIG. 1A is a top view of a semiconductor device, and FIG. 1B is a cross-sectional view along line C1-C1 of FIG. 1A. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include crystalline semiconductor material, such as germanium (Ge) or silicon (Si). Other suitable semiconductor material may include silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), or combinations thereof. In some embodiments, the substrate 100 is un-doped.

A semiconductor layer 104A is formed over the substrate 100. In some embodiments, the semiconductor layer 104A may be a doped semiconductor layer. For example, the semiconductor layer 104A may include p-type dopants or n-type dopants. In some embodiments, exemplary p-type dopants may include boron (B), gallium (Ga), indium (In), aluminium (Al), or the like. In some embodiments, exemplary n-type dopants may include phosphorus (P), arsenic (As), or antimony (Sb), or the like. The semiconductor layer 104A may be formed over the substrate 100 using suitable deposition process, such as selective epitaxial growth (SEG), such that the semiconductor layer 104A can be selectively grown on a semiconductor material, such as the substrate 100. In some embodiments, an implantation process may be performed to dope the semiconductor layer 104A during or after the formation of the semiconductor layer 104A.

For a p-type device, the substrate 100 may be a germanium (Ge) layer, and the semiconductor layer 104A may be a semiconductor material with p-type dopants, such as a boron-doped germanium (Ge:B) layer. On the other hand, for an n-type device, the substrate 100 may be a silicon layer, and the semiconductor layer 104A may be a semiconductor material with n-type dopants, such as a phosphorus-doped silicon (Si:P) layer. The semiconductor layer 104A may function as a solid phase dopant source for the following solid phase diffusion process. In some embodiments, the semiconductor layer 104A and the substrate 100 may include a same material.

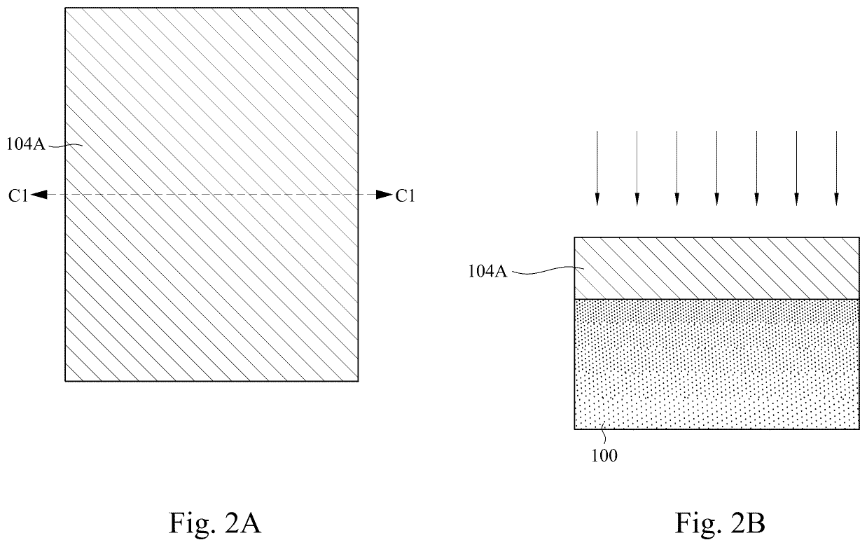

Reference is made to FIGS. 2A and 2B, in which FIG. 2A is a top view of a semiconductor device, and FIG. 2B is a cross-sectional view along line C1-C1 of FIG. 2A. After the semiconductor layer 104A is formed, a thermal annealing process is performed. The annealing process may allow solid phase diffusion (drive-in) of the dopants in the solid phase dopant source (e.g., the semiconductor layer 104A), such that the dopants in the semiconductor layer 104A are driven into the substrate 100. For example, when the semiconductor layer 104A includes p-type dopants, the p-type dopants may be driven from the semiconductor layer 104A into the substrate 100. Similarly, when the semiconductor layer 104A includes n-type dopants, the n-type dopants may be driven from the semiconductor layer 104A into the substrate 100. In some embodiments, the doped region in the substrate 100 may include a gradient concentration as a result of the thermal annealing process. For example, the dopants may include a maximum concentration at the top surface of the substrate 100, and the dopant concentration may decrease downward toward the bottom surface of the substrate 100.

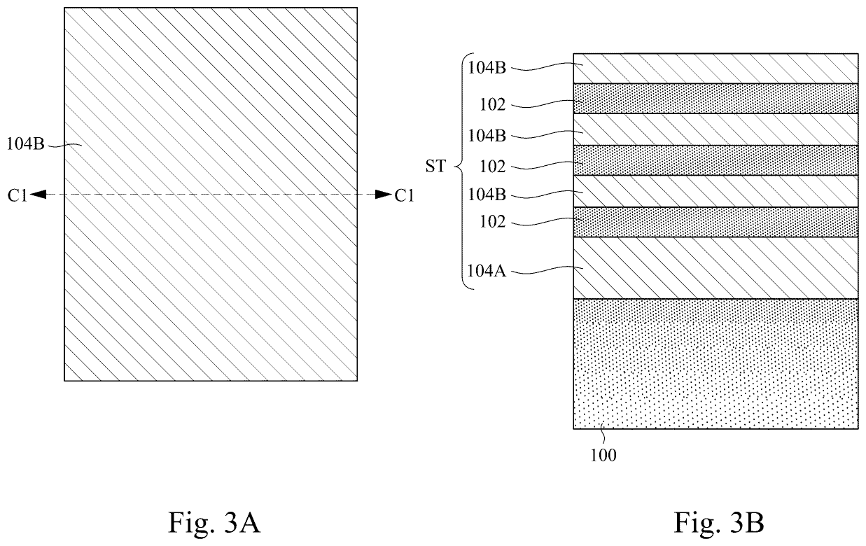

Reference is made to FIGS. 3A and 3B, in which FIG. 3A is a top view of a semiconductor device, and FIG. 3B is a cross-sectional view along line C1-C1 of FIG. 3A. After the thermal annealing process of FIGS. 2A and 2B is complete, semiconductor layers 102 and semiconductor layers 104B are alternately deposited over the semiconductor layer 104A, so as to form a semiconductor stack (ST). In some embodiments, the semiconductor stack (ST) may include the semiconductor layers 102, 104A, and 104B. In some embodiments, the semiconductor layers 102 and semiconductor layers 104B may be deposited using suitable deposition process, such as selective epitaxial growth (SEG), chemical vapor deposition (CVD), molecular beam epitaxy (MBE), or other suitable process(es). The semiconductor layers 102 may serve as channel layers of a semiconductor device, and can also be referred to as semiconductor channel layers. The semiconductor layers 104A and 104B may be removed during a replacement gate (RPG) process, and thus the semiconductor layers 104A and 104B may also be referred to as sacrificial layers, in which the semiconductor layer 104A is the bottommost sacrificial layer.

In some embodiments, the semiconductor layers 102 may include a channel material, such as silicon (Si), germanium (Ge), tin (Sn), silicon germanium (Si₁₋ₓGeₓ), germanium tin (Ge_{1-y}Sn_{y}), silicon germanium tin (Si_{1-x-y}GeₓSn_{y}), III-V material, or other suitable channel material. In some embodiments, the semiconductor layers 102 may include a material different from the semiconductor layers 104A and 104B, so as to provide sufficient etching selectivity from the semiconductor layers 104A and 104B.

In some embodiments, the semiconductor layers 104B may include a same material or a similar material as the semiconductor layer 104A. As mentioned above, the semiconductor layer 104A may be doped with p-type or n-type dopants for solid phase diffusion, while the semiconductor layers 104B may be free of the p-type or n-type dopants in the semiconductor layer 104A. For example, in some embodiment, the semiconductor layer 104A may be a germanium layer doped with boron (B), and the semiconductor layers 104B may be a germanium layer that is substantially free of boron (B).

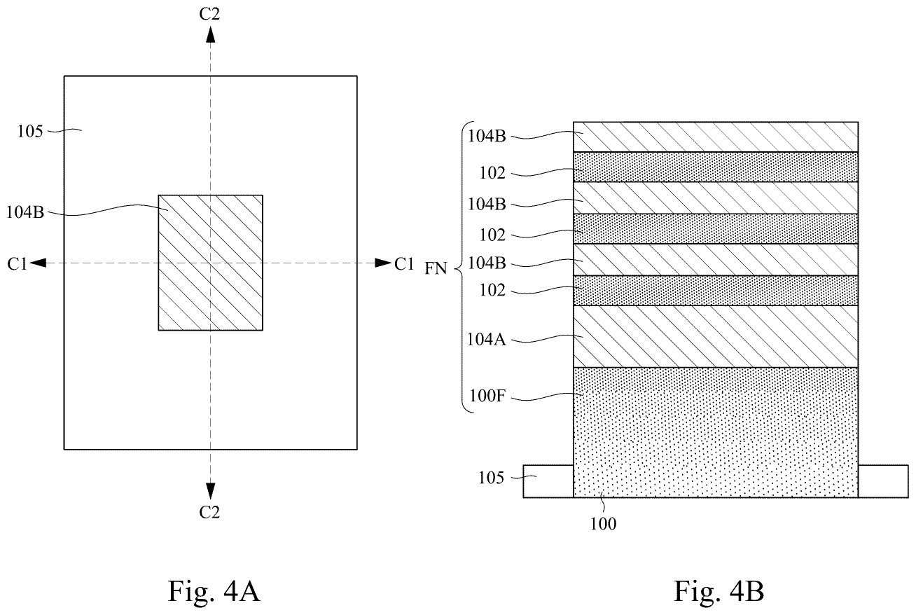

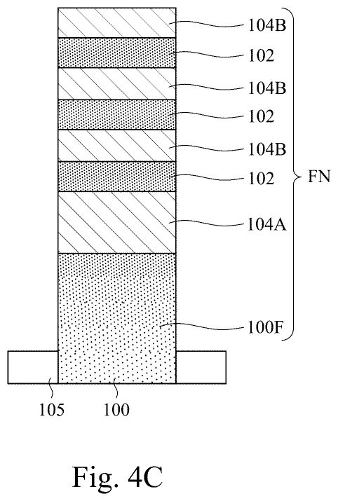

Reference is made to FIGS. 4A to 4C, in which FIG. 4A is a top view of a semiconductor device, FIG. 4B is a cross-sectional view along line C1-C1 of FIG. 4A, and FIG. 4C is a cross-sectional view along line C2-C2 of FIG. 4A, respectively. The substrate 100 and the semiconductor stack ST are patterned to form a fin structure FN. In some embodiments, a mask (not shown) is formed over the semiconductor stack ST, in which the mask defines the position and the profile of the fin structure FN. An etching process is performed to remove portions of the semiconductor stack ST and the substrate 100 exposed through the mask, leaving the remaining portions of the semiconductor stack ST and the substrate 100 as the fin structure FN. The mask is then removed once the fin structure FN is formed. In some embodiments, after the patterning process, the substrate 100 may include a semiconductor fin 100F. The fin structure FN may include the remaining portion of the semiconductor stack ST and the semiconductor fin 100F.

An isolation structure 105 is formed over the substrate 100 and laterally surrounding a lower portion of the semiconductor fin 100F. In some embodiments, the isolation structure 105 may be in contact with sidewalls of the semiconductor fin 100F. The isolation structure 105 may be shallow trench isolation (STI) structures, suitable isolation structures, combinations of the foregoing, or the like. In some embodiments, the isolation structure 105 may be made of oxide (e.g., silicon oxide), nitride (e.g., silicon nitride), or combinations thereof.

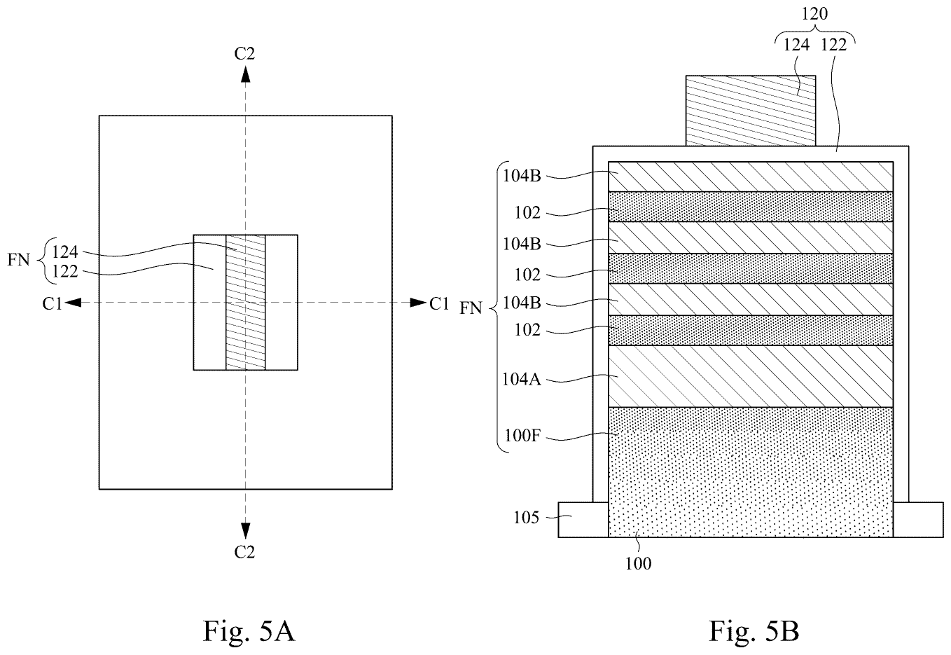

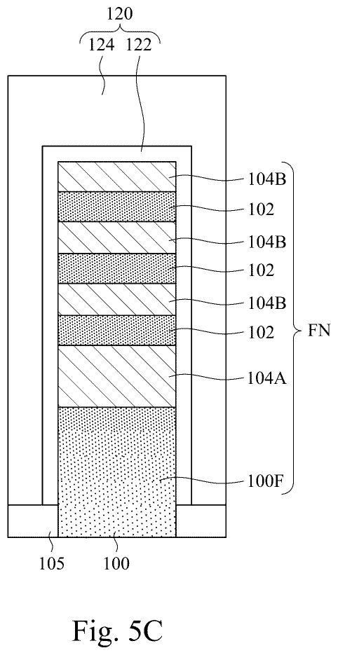

Reference is made to FIGS. 5A to 5C, in which FIG. 5A is a top view of a semiconductor device, FIG. 5B is a cross-sectional view along line C1-C1 of FIG. 5A, and FIG. 5C is a cross-sectional view along line C2-C2 of FIG. 5A, respectively. A dummy gate structure 120 is formed over the substrate 100 and crossing the fin structure FN. In some embodiments, the dummy gate structure 120 includes a dummy gate dielectric 122 and a dummy gate electrode 124 over the dummy gate dielectric 122. The dummy gate dielectric 122 may be, for example, silicon oxide, silicon nitride, a combination thereof, or the like, and may be deposited or thermally grown according to acceptable techniques. The dummy gate electrode 124 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. In some embodiments, the dummy gate electrode 124 may be deposited by physical vapor deposition (PVD), chemical vapor deposition (CVD), sputter deposition, or other techniques for depositing the selected material. In some embodiments, the dummy gate dielectric 122 may be formed by thermal oxidation.

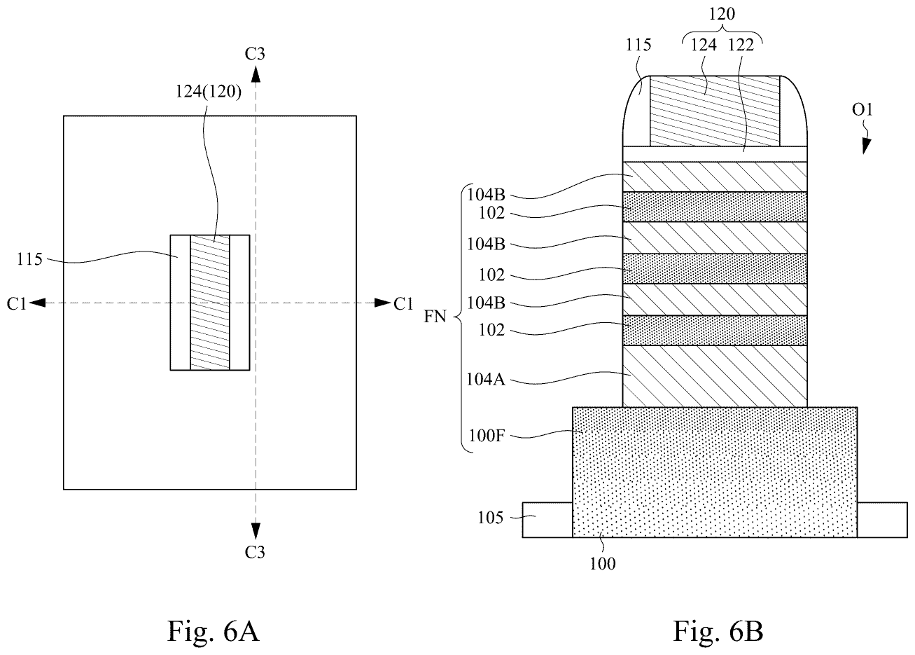

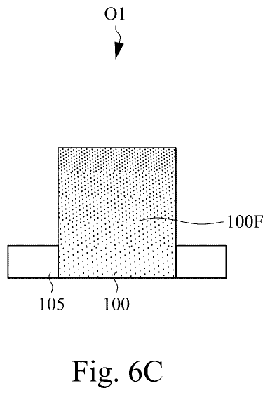

Reference is made to FIGS. 6A to 6C, in which FIG. 6A is a top view of a semiconductor device, FIG. 6B is a cross-sectional view along line C1-C1 of FIG. 6A, and FIG. 6C is a cross-sectional view along line C3-C3 of FIG. 6A, respectively. Gate spacers 115 are formed on opposite sidewalls of the dummy gate structure 120. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate 100, and then performing an anisotropic etching process to remove horizontal portions of the spacer layer, such that vertical portions of the spacer layer remain on sidewalls of the dummy gate structure 120. In some embodiments, the spacer layer may be deposited using techniques such CVD, ALD, or the like.

An etching process is performed to remove portions of the dummy gate dielectric 122 and the fin structure FN by using the dummy gate electrode 124 and the gate spacers 115 as etch mask, so as to form source/drain openings O1 in the fin structure FN. In some embodiments, the etching process may be stopped once the top surface of the semiconductor fin 100F is exposed. In some embodiments, the etching process may be wet etch, dry etch, or combinations thereof.

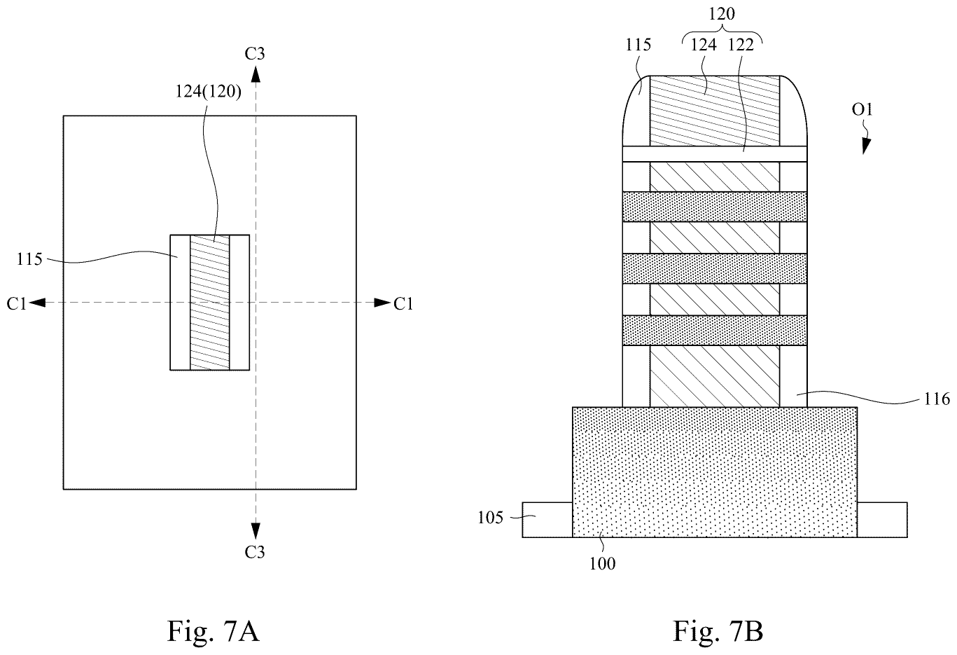

Reference is made to FIGS. 7A and 7B, in which FIG. 7A is a top view of a semiconductor device, and FIG. 7B is a cross-sectional view along line C1-C1 of FIG. 7A. After the source/drain openings O1 are formed, inner spacers 116 are formed on opposite ends of each of the semiconductor layers 104A and 104B. The inner spacers 116 can be formed by, for example, performing an etching process to laterally etch the semiconductor layers 104A and 104B to form sidewall recesses, depositing a dielectric material blanket over the substrate 100 and filling the sidewall recesses, and then performing an anisotropic etching to remove portions of the dielectric material outside the sidewall recesses, leaving the remaining portions of the dielectric material in the sidewall recesses as the inner spacers 116. The inner spacers 116 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

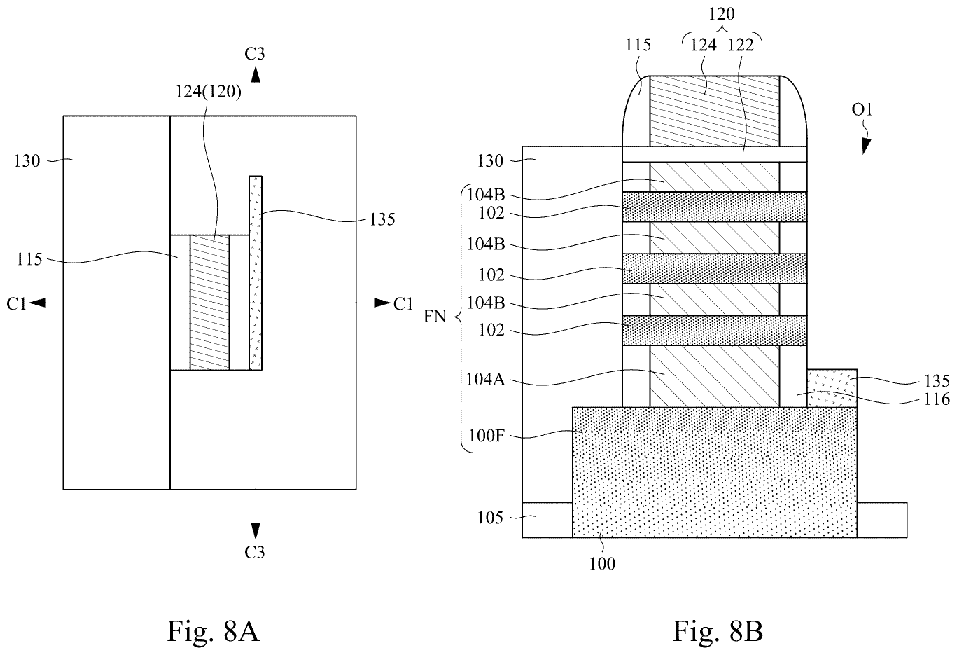

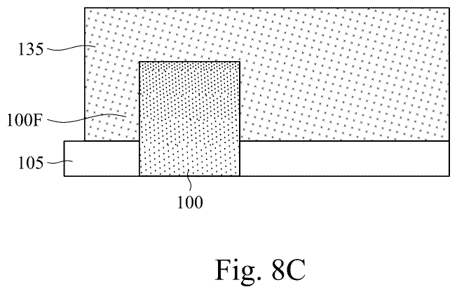

Reference is made to FIGS. 8A to 8C, in which FIG. 8A is a top view of a semiconductor device, FIG. 8B is a cross-sectional view along line C1-C1 of FIG. 8A, and FIG. 8C is a cross-sectional view along line C3-C3 of FIG. 8A, respectively. An isolation layer 130 is formed over the substrate 100 and filling one of the source/drain openings O1, so as to cover a portion of the top surface of the semiconductor fin 100F. In some embodiments, the isolation layer 130 may include oxide (e.g., silicon oxide), nitride (e.g., silicon nitride), or the like. The isolation layer 130 may be formed by, for example, depositing a dielectric material over the substrate 100, and then patterning the dielectric material.

After the isolation layer 130 is formed, a source/drain electrode 135 is formed over the substrate 100, and crossing at least a portion of the semiconductor fin 100F through another one of the source/drain openings O1. As shown in the cross-sectional view of FIG. 8C, the source/drain electrode 135 may be in contact with the top surface and opposite sidewalls of a portion of the semiconductor fin 100F, and may also be in contact with top surface of the isolation structure 105. In some embodiments, the source/drain electrode 135 may include suitable conductive material, such as platinum (Pt), titanium (Ti), titanium nitride (TiN), aluminum (Al), tungsten (W), tungsten nitride (WN), ruthenium (Ru), ruthenium oxide (RuO), tantalum (Ta), tantalum nitride (TaN), nickel (Ni), Cobalt (Co), Copper (Cu), silver (Ag), gold (Au), alloys thereof, combinations thereof, and the like.

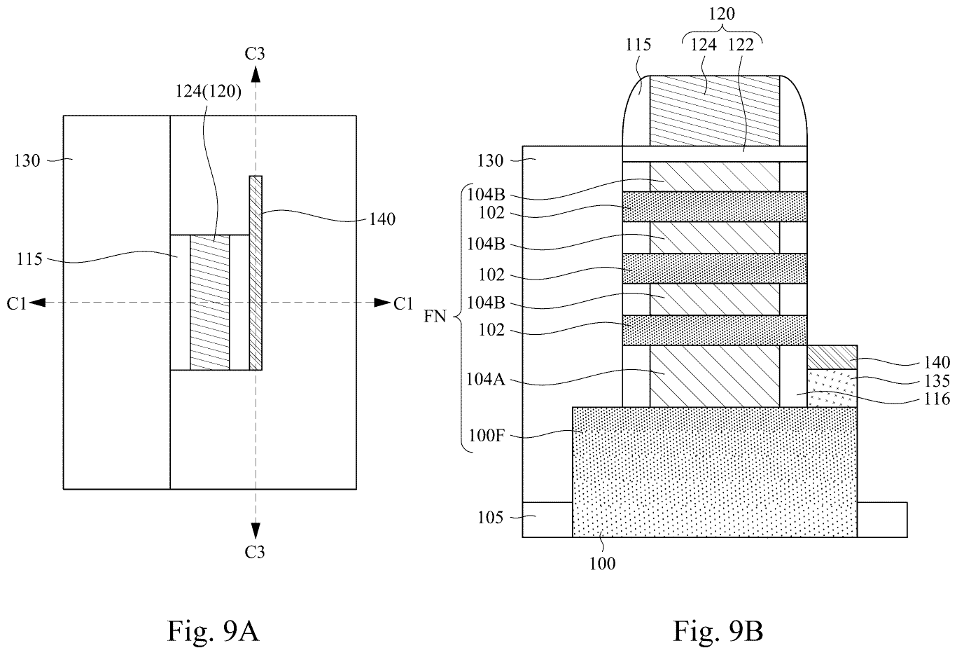

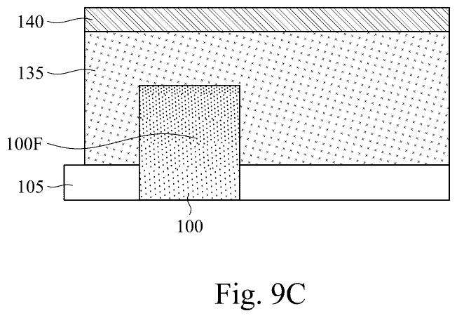

Reference is made to FIGS. 9A to 9C, in which FIG. 9A is a top view of a semiconductor device, FIG. 9B is a cross-sectional view along line C1-C1 of FIG. 9A, and FIG. 9C is a cross-sectional view along line C3-C3 of FIG. 9A, respectively. An isolation layer 140 is formed over the substrate 100 and covering the source/drain electrode 135. In some embodiments, the isolation layer 140 may be made of a low-k dielectric material, such as SiOCN, SiOC and/or other suitable dielectric material. The isolation layer 140 may be formed by, for example, depositing a dielectric material blanket over the substrate 100, and then patterning the dielectric material.

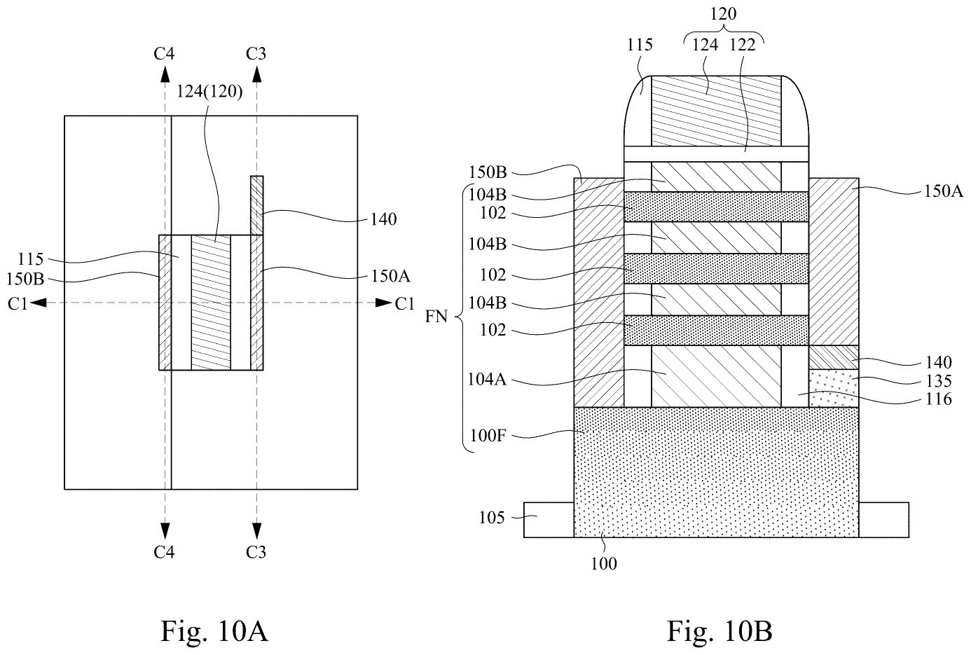

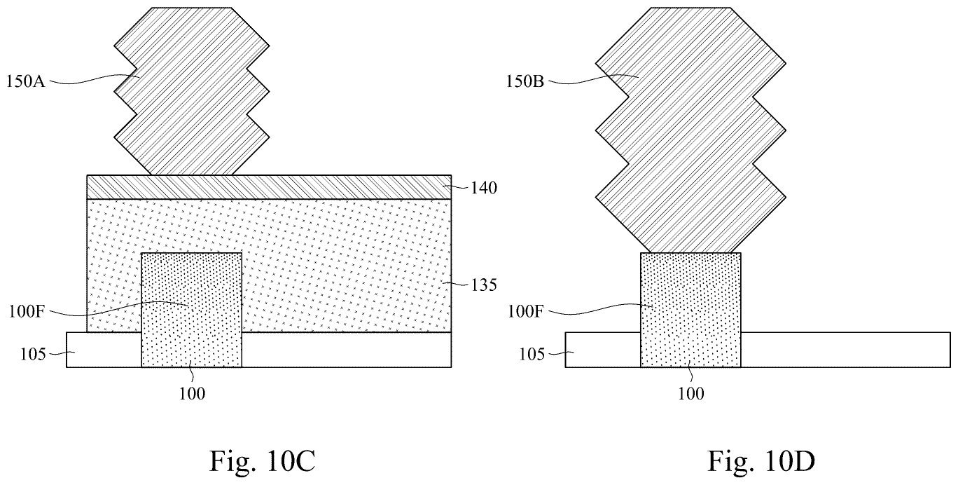

Reference is made to FIGS. 10A to 10D, in which FIG. 10A is a top view of a semiconductor device, FIG. 10B is a cross-sectional view along line C1-C1 of FIG. 10A, FIG. 10C is a cross-sectional view along line C3-C3 of FIG. 10A, and FIG. 10D is a cross-sectional view along line C4-C4 of FIG. 10A, respectively. Once the isolation layer 140 is formed, the isolation layer 130 may be removed using suitable etching process. Then, source/drain epitaxy structures 150A and 150B are formed in the source/drain openings O1 and on opposite ends of each of the semiconductor layers 102. In some embodiments, the source/drain epitaxy structures 150A and 150B may include semiconductor material, such as silicon germanium (SiGe), or other suitable semiconductor material. For example, the source/drain epitaxy structures 150A and 150B may be Si_{0.1}Ge_{0.9}. In some embodiments, the source/drain epitaxy structures 150A and 150B may be formed by a selective epitaxial growth (SEG) process. The SEG process may selectively grow a semiconductor material on exposed semiconductor surfaces, such as the exposed surfaces of the semiconductor layers 102.

In some embodiments, the source/drain epitaxy structures 150A and 150B may be doped with p-type dopants or n-type dopants. In some embodiments, the dopants of the source/drain epitaxy structures 150A and 150B may include an opposite conductivity type than the dopants of the semiconductor layer 104A and the dopants driven into the semiconductor fin 100F. For example, if the semiconductor layer 104A and the semiconductor fin 100F include p-type dopants, the source/drain epitaxy structures 150A and 150B may include n-type dopants, and vice versa.

In some embodiments, the source/drain epitaxy structures 150A and 150B may include different profiles. Because of the present of the source/drain electrode 135 and the isolation layer 140, the source/drain epitaxy structure 150A may be separated from the semiconductor fin 100F through the isolation layer 140 and the source/drain electrode 135, and may be formed in contact with top surface of the isolation layer 140. On the other hand, the source/drain epitaxy structure 150B may be in contact with the semiconductor fin 100F. As a result, the bottom surface of the source/drain epitaxy structure 150B is lower than the bottom surface of the source/drain epitaxy structure 150A.

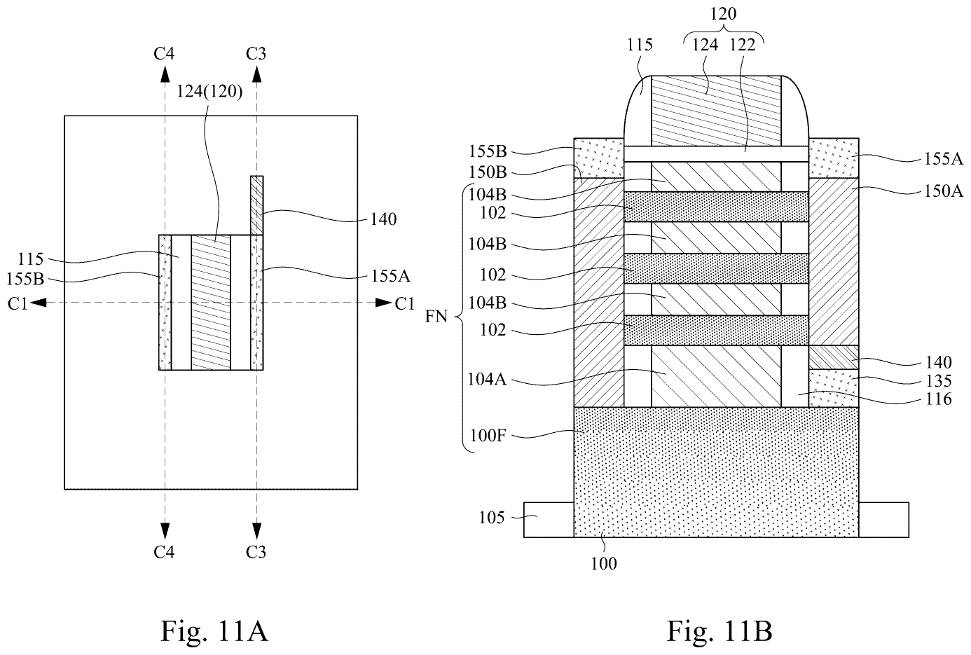

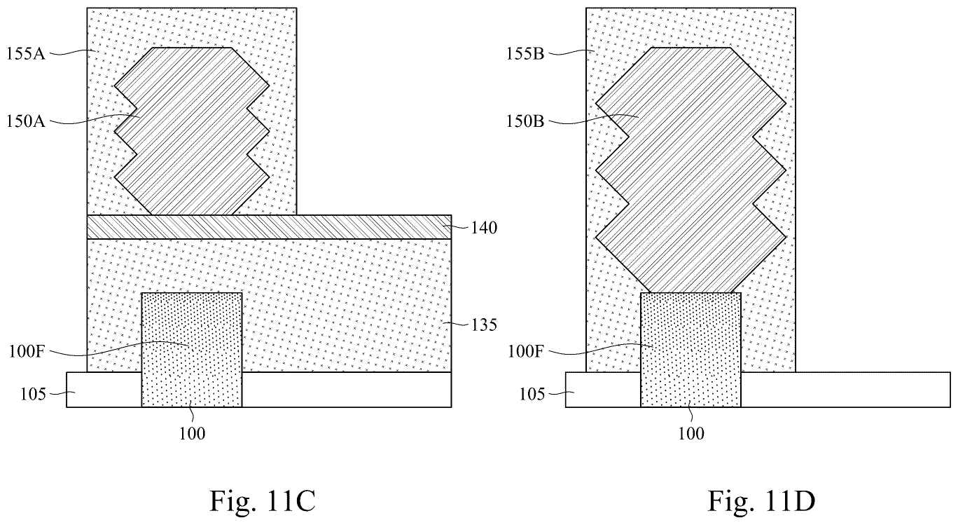

Reference is made to FIGS. 11A to 11D, in which FIG. 11A is a top view of a semiconductor device, FIG. 11B is a cross-sectional view along line C1-C1 of FIG. 11A, FIG. 11C is a cross-sectional view along line C3-C3 of FIG. 11A, and FIG. 11D is a cross-sectional view along line C4-C4 of FIG. 11A, respectively. Source/drain contacts 155A and 155B are formed over the substrate 100 and covering the source/drain epitaxy structures 150A and 150B, respectively. In some embodiments, the source/drain contacts 155A and 155B may include suitable conductive material, such as platinum (Pt), titanium (Ti), titanium nitride (TiN), aluminum (Al), tungsten (W), tungsten nitride (WN), ruthenium (Ru), ruthenium oxide (RuO), tantalum (Ta), tantalum nitride (TaN), nickel (Ni), Cobalt (Co), Copper (Cu), silver (Ag), gold (Au), alloys thereof, combinations thereof, and the like. The source/drain contacts 155A and 155B may be formed by, for example, depositing a conductive material over the substrate 100, and then patterning the conductive material.

In some embodiments, the source/drain contact 155A is in contact with top surface of the isolation layer 140, and may be vertically separated from the source/drain electrode 135 through the isolation layer 140. On the other hand, the source/drain contact 155B may be in contact with opposite sidewalls of the semiconductor fin 100F, and top surface of the isolation structure 105. In some embodiments, the bottom surface of the source/drain contact 155B is lower than the bottom surface of the source/drain contact 155A.

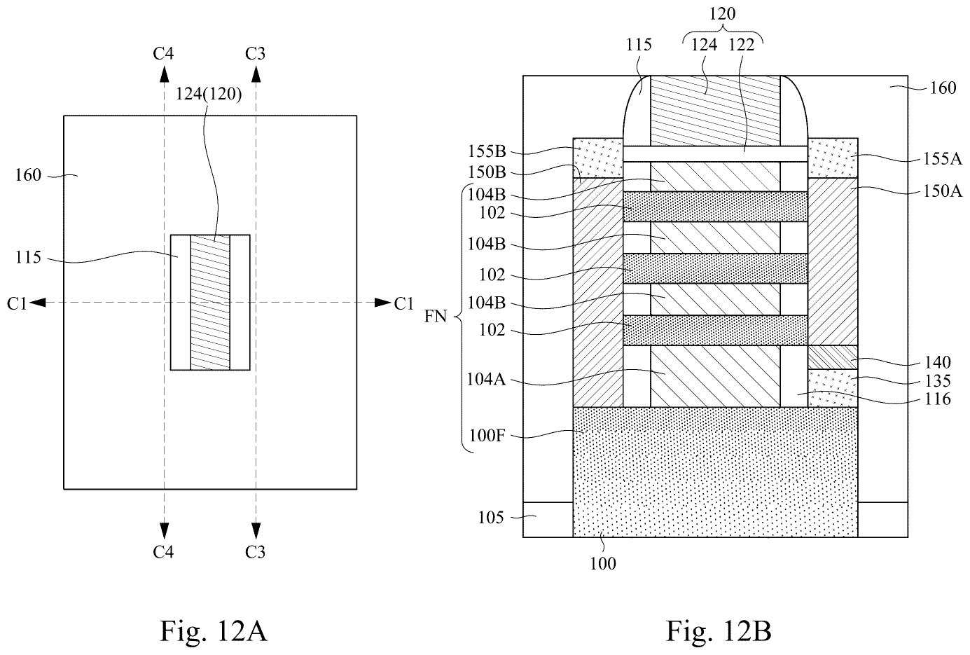

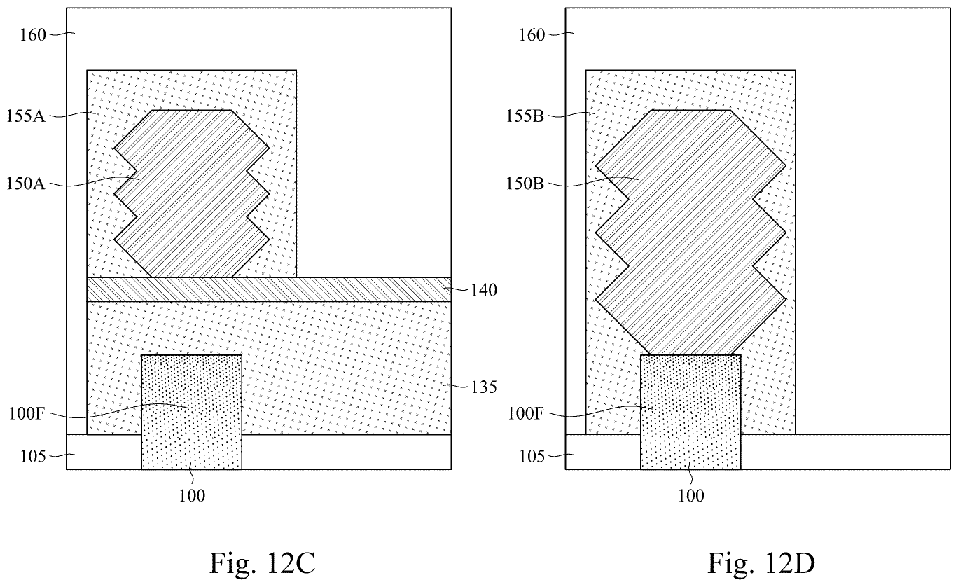

Reference is made to FIGS. 12A to 12D, in which FIG. 12A is a top view of a semiconductor device, FIG. 12B is a cross-sectional view along line C1-C1 of FIG. 12A, FIG. 12C is a cross-sectional view along line C3-C3 of FIG. 12A, and FIG. 12D is a cross-sectional view along line C4-C4 of FIG. 12A, respectively. An interlayer dielectric (ILD) layer 160 is formed over the substrate 100 and covering the source/drain contacts 155A and 155B. In some embodiments, the ILD layer 160 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. A planarization process may be performed to remove excess material of the ILD layer 160 until the dummy gate structure 120 is exposed.

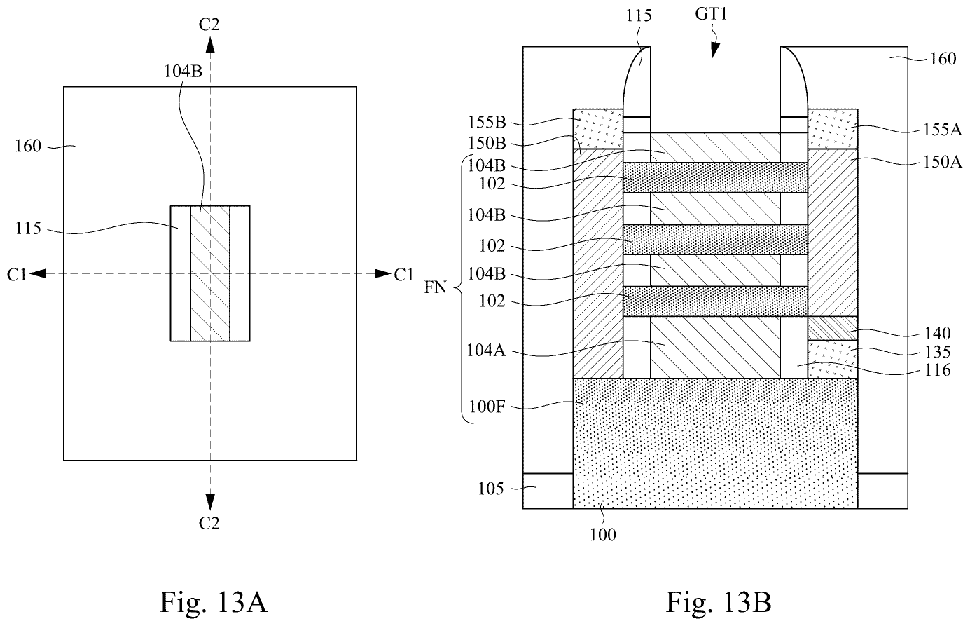

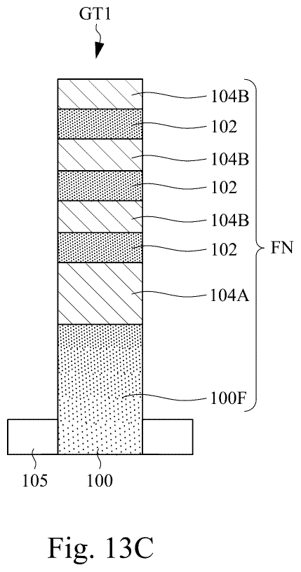

Reference is made to FIGS. 13A to 13C, in which FIG. 13A is a top view of a semiconductor device, FIG. 13B is a cross-sectional view along line C1-C1 of FIG. 13A, and FIG. 12C is a cross-sectional view along line C2-C2 of FIG. 12A, respectively. The dummy gate structure 120 is removed to form gate trench GT1 between the gate spacers 115. As shown in FIG. 13C, once the dummy gate structure 120 is removed, portion of the fin structure FN may be exposed through the gate trench GT1. In some embodiments, at least portions of the dummy gate dielectric 122 may remain under the gate spacers 115 after the removal of the dummy gate structure 120 (see FIG. 13B).

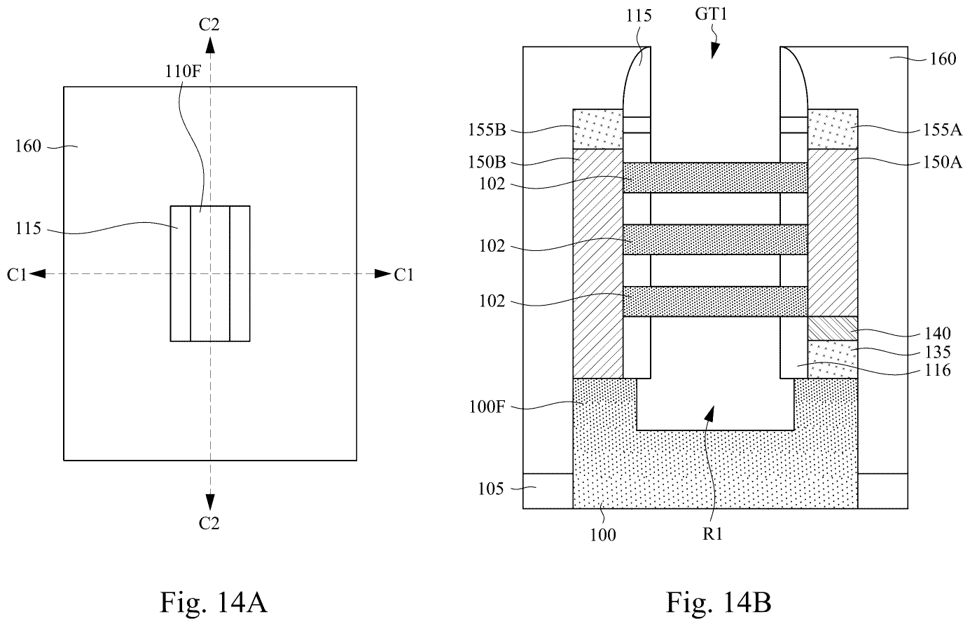

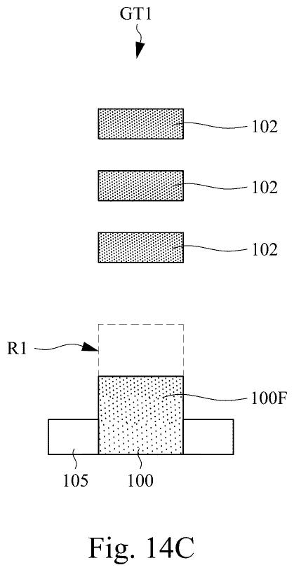

Reference is made to FIGS. 14A to 14C, in which FIG. 14A is a top view of a semiconductor device, FIG. 14B is a cross-sectional view along line C1-C1 of FIG. 14A, and FIG. 14C is a cross-sectional view along line C2-C2 of FIG. 14A, respectively. An etching process is performed to remove the semiconductor layers 104A and 104B through the gate trench GT1, such that the semiconductor layers 102 are suspended over the substrate 100. In some embodiments, because the semiconductor fin 100F of the substrate 100 may include a similar material as the semiconductor layers 104A and 104B, the etching process may include higher etching rate to the semiconductor fin 100F and the semiconductor layers 104A and 104B than to the semiconductor layers 102. As a result, a portion of the semiconductor fin 100F may also be removed, such that a recess R1 is formed in the semiconductor fin 100F. As shown in FIG. 14B, in some embodiments, due to lateral etch of the semiconductor fin 100F, the width of the recess R1 may be wider than the width of the gate trench GT1. Accordingly, the recess may expose bottom surfaces of the bottommost inner spacers 116.

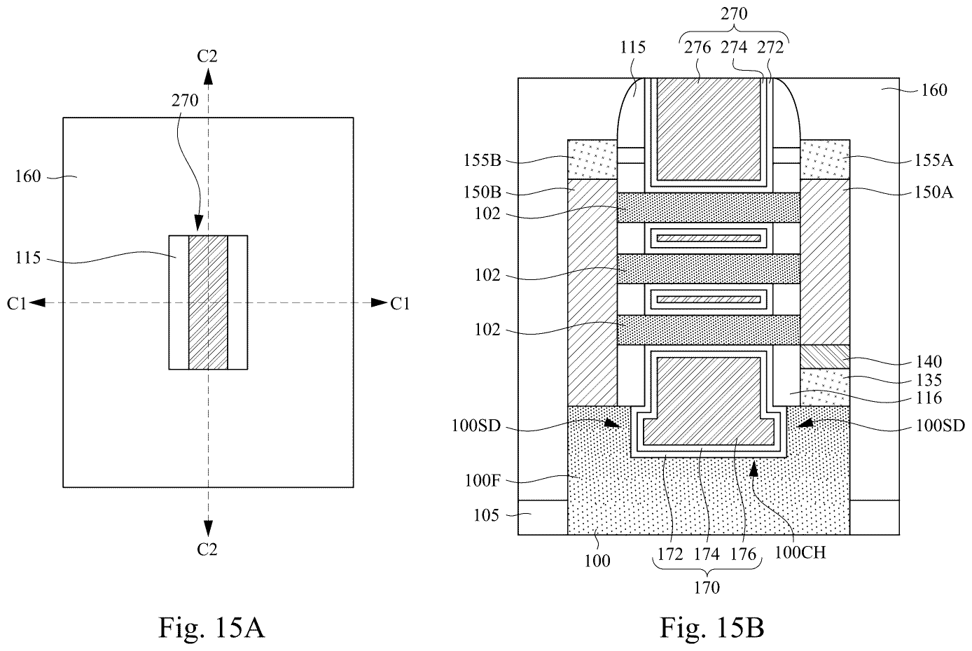

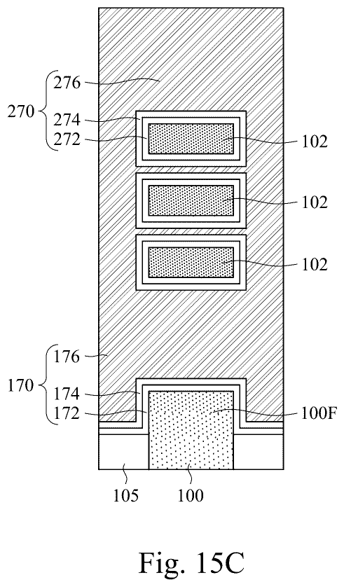

Reference is made to FIGS. 15A to 15C, in which FIG. 15A is a top view of a semiconductor device, FIG. 15B is a cross-sectional view along line C1-C1 of FIG. 15A, and FIG. 15C is a cross-sectional view along line C2-C2 of FIG. 15A, respectively. A gate dielectric layer 172 is formed on the exposed surface of the semiconductor fin 100F, and a gate dielectric layer 272 is formed on the exposed surfaces of the semiconductor layers 102. Then, work function metal layers 174 and 274 are formed over the gate dielectric layers 172 and 272, respectively. In some embodiments, the gate dielectric layers 172 and 272 may be formed using a same deposition process and may include a same material, and the work function metal layers 174 and 274 may be formed using a same deposition process and may include a same material.

After the gate dielectric layers 172 and 272 and the work function metal layer 174 and 274 are formed, a gate filling metal material is formed in the recess R1 and the gate trench GT1. The portion of the gate filling metal material over the work function metal layer 174 can be referred to as a gate filling metal 176, and the portion of the gate filling metal material over the work function metal layer 274 can be referred to as a gate filling metal 276. That is, the gate filling metals 176 and 276 may be different portions of a gate filling metal material.

The gate dielectric layer 172, the work function metal layer 174, and the gate filling metal 176 can be collectively referred to as a metal gate structure 170. The gate dielectric layer 272, the work function metal layer 274, and the gate filling metal 276 can be collectively referred to as a metal gate structure 270. In some embodiments, the metal gate structure 170 is embedded in the semiconductor fin 100F and may include a wider width than the metal gate structure 270. Accordingly, the metal gate structure 170 may be in contact with bottom surfaces of the bottommost inner spacers 116.

In some embodiments, the gate dielectric layers 172 and 272 each may include an interfacial layer and a high-k dielectric layer over the interfacial layer. Examples of interfacial layer may include oxide, such as aluminum oxide (Al₂O₃), silicon oxide (SiO₂), or the like. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The work function metal layers 174 and 274 may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The gate filling metals 176 and 276 may include tungsten (W), aluminum (Al), copper (Cu), or another suitable conductive material(s).

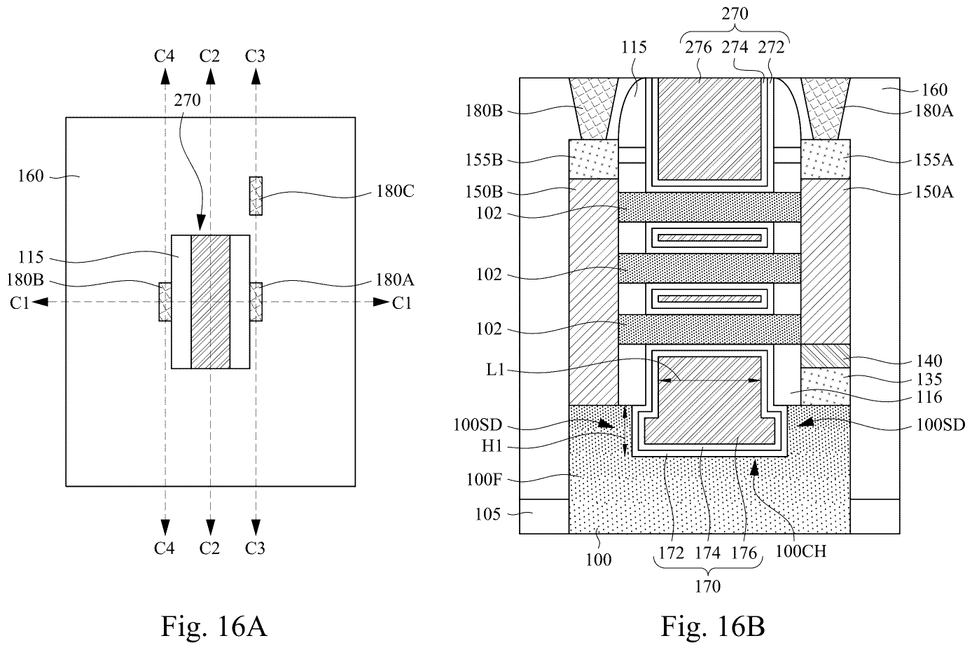

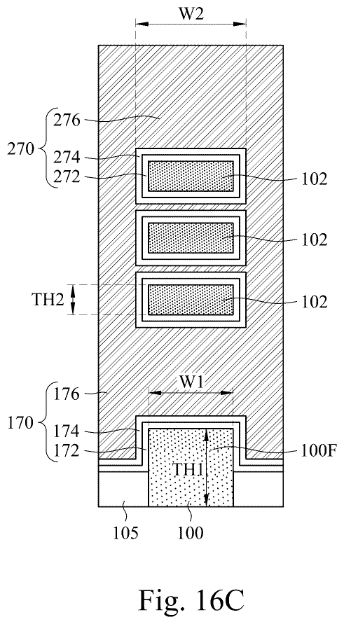

Reference is made to FIGS. 16A to 16E, in which FIG. 16A is a top view of a semiconductor device, FIG. 16B is a cross-sectional view along line C1-C1 of FIG. 16A, FIG. 16C is a cross-sectional view along line C2-C2 of FIG. 16A, FIG. 16D is a cross-sectional view along line C3-C3 of FIG. 16D, and FIG. 16E is a cross-sectional view along line C4-C4 of FIG. 16E, respectively. Source/drain vias 180A, 180B, and 180C are formed in the ILD layer 160. In greater detail, the source/drain via 180A is formed in contact with the source/drain contact 155A, the source/drain via 180B is formed in contact with the source/drain contact 155B, and the source/drain via 180C is formed in contact with the source/drain electrode 135. The source/drain vias 180A, 180B, and 180C may include suitable conductive material, such as platinum (Pt), titanium (Ti), titanium nitride (TiN), aluminum (Al), tungsten (W), tungsten nitride (WN), ruthenium (Ru), ruthenium oxide (RuO), tantalum (Ta), tantalum nitride (TaN), nickel (Ni), Cobalt (Co), Copper (Cu), silver (Ag), gold (Au), alloys thereof, combinations thereof, and the like. The source/drain vias 180A, 180B, and 180C may be formed by, for example, patterning the ILD layer 160 to form openings that expose the source/drain contacts 155A and 155B, and the source/drain electrode 135, respectively, filing the openings with conductive material, and then performing a planarization to remove excess material of the conductive material until the ILD layer 160 is exposed.

The structure of FIGS. 16A to 16E is an example of a complementary FET (CFET), which may include a first transistor and a second transistor vertically stacked above the first transistor. In greater detail, the semiconductor fin 100F and the metal gate structure 170 may collectively function as the first transistor. On the other hand, the semiconductor layers 102, the metal gate structure 270, and the source/drain epitaxy structures 150A and 150B may collectively function as the second transistor. In some embodiments, the first transistor and the second transistor may include opposite conductivities. For example, the first transistor may be a p-type transistor, and the second transistor may be an n-type transistor, and vice versa.

With respect to the first transistor, the first transistor may include a fin-type configuration, and thus the first transistor can also be referred to as a FinFET device. In greater detail, the metal gate structure 170 may cross the semiconductor fin 100F in the cross-sectional view of FIG. 16C. That is, the metal gate structure 170 may be in contact with three sides of the semiconductor fin 100F. With respect to the second transistor, the second transistor may include a gate-all-around (GAA) configuration, and thus the first transistor can also be referred to as a GAA device. In greater detail, the metal gate structure 270 may wrap around each of the semiconductor layers 102 in the cross-sectional view of FIG. 16C. That is, the metal gate structure 270 may be in contact with four sides of the each of the semiconductor layers 102.

As shown in the cross-sectional view of FIG. 16B, the semiconductor fin 100F includes a channel portion 100CH in contact with the bottom surface of the metal gate structure 170. The semiconductor fin 100F further includes source/drain portions 100SD on opposite sides of the channel portion 100CH, and in contact with opposite sidewalls of the metal gate structure 170. Accordingly, the semiconductor fin 100F may include a saddle-shape cross-sectional profile.

As discussed above, during the removal process as discussed in FIGS. 14A to 14C, a recess R1 is formed in the semiconductor fin 100F. This will result in that the metal gate structure 170 is embedded in the semiconductor fin 100F, resulting the topmost surface of the channel portion 100CH being lower than the topmost surface of the source/drain portions 100SD. Moreover, during the solid phase diffusion process as discussed in FIGS. 2A and 2B, the semiconductor fin 100F may include a gradient dopant concentration, in which the dopant concentration in the semiconductor fin 100F may decrease downward from the top surface of the semiconductor fin 100F. As a result, the dopant concentration in the channel portion 100CH will be lower than the dopant concentration in the source/drain portions 100SD. In some embodiments, the top surface of the channel portion 100CH may include a dopant concentration in a range from about 1×10¹⁰ cm⁻³ to about 1×10¹⁸ cm⁻³. In some embodiments, each of the source/drain portions 100SD may include a maximum dopant concentration at the topmost surface of the semiconductor fin 100F and in a range from about 1×10¹⁸ cm⁻³ to about 1×10²² cm⁻³. In some embodiments, the maximum dopant concentration at the topmost surface of the source/drain portions 100SD may be at least 10 times the maximum dopant concentration at the topmost surface of the channel portion 100CH. Moreover, the source/drain portions 100SD may also include a gradient dopant concentration, in which the dopant concentration in the source/drain portion 100SD may decrease downward from the top surface of the semiconductor fin 100F. In greater detail, the dopant concentration at the surface of the source/drain portion 100SD that is in contact with the metal gate structure 170 may decrease downwardly.

The channel portion 100CH with lower dopant concentration may be beneficial to improve the device performance of the first transistor. In some embodiments where the recess R1 of FIGS. 14A and 14B is not formed, the resulting channel portion 100CH of the semiconductor fin 100F may be at a same level as the source/drain portions 100SD, and will include substantially the same dopant concentration. Accordingly, during the operation of the first transistor, current leakage may occur from one source/drain portion 100SD to another source/drain portion 100SD through the channel portion 100CH, which can also be referred to as a “punch-through effect.” In the embodiments of the present disclosure, the channel portion 100CH at a lower position with lower dopant concentration is able to suppress the current leakage, and thus the device performance will be improved.

In FIG. 16B, the portion of the metal gate structure 170 embedded in the semiconductor fin 100F may include a height H1. In some embodiments, the height H1 is in a range from about 25 nm to about 35 nm, such as 30 nm. If the height H1 is too small, the dopant concentration of the channel portion 100CH may be too high, and may not be able to suppress the current leakage. If the height H1 is too large, the dopant concentration of the channel portion 100CH may be too low, and the device performance may not be satisfying. The metal gate structure 270 may include a gate length L1. In some embodiments, the gate length L1 is in a range from about 1 nm to about 200 nm, such as 12 nm.

In FIG. 16C, the semiconductor fin 100F (or the channel portion 100H of the semiconductor fin 100F) may include a thickness TH1 and a width W1. In some embodiments, the thickness TH1 is in a range from about 1 nm to about 200 nm. The width W1 is in a range from about 1 nm to about 200 nm, such as 25 nm. The semiconductor layers 102 each may include a thickness TH2 and a width W2. In some embodiments, the thickness TH2 is in a range from about 1 nm to about 200 nm, such as 5 nm. The width W2 is in a range from about 1 nm to about 200 nm, such as 25 nm. In other embodiments, the semiconductor layers 102 may include different thicknesses TH2. In some embodiments, the vertical distances between adjacent semiconductor layers 102 can be different. In some embodiments, the vertical distances between adjacent semiconductor layers 102 is in a range from about 3 nm to about 200 nm. In some embodiments, the number of the semiconductor layers 102 may be in a range from about 2 to 20. In some embodiments, the cross-sectional profiles of the semiconductor layers 102 may be rectangle, square, diamond, etc., with or without rounded corners.

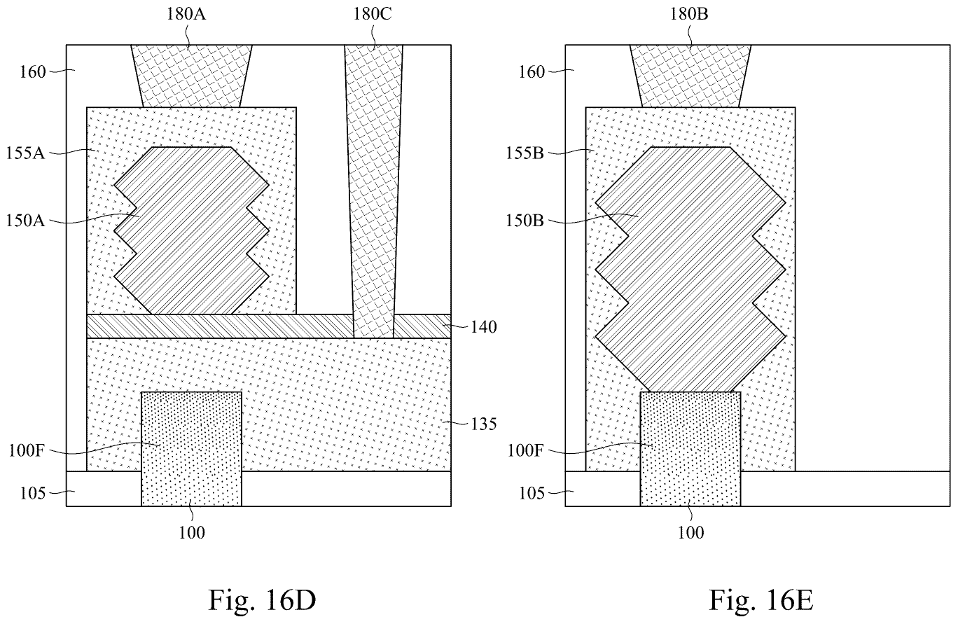

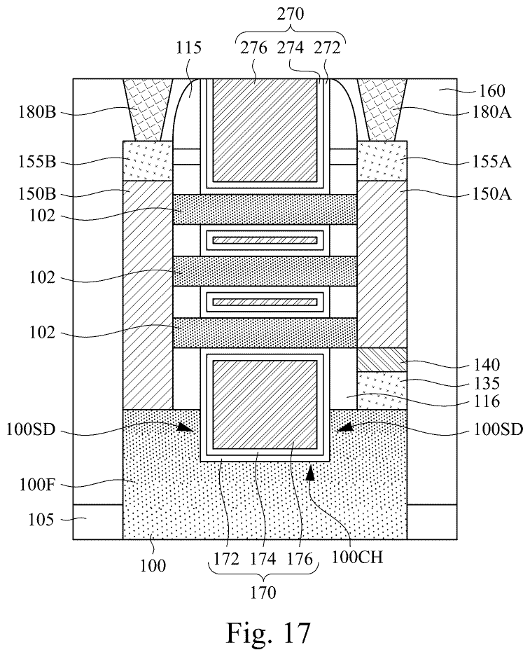

FIG. 17 is a cross-sectional view of a semiconductor device in accordance with some embodiments of the present disclosure. FIG. 17 is similar to FIG. 16B, and thus similar elements are labeled the same, and relevant details will not be repeated for brevity. FIG. 17 is different from FIG. 16B, in that the metal gate structure 170 embedded in the semiconductor fin 100F may include substantially a same width as the metal gate structure 270. That is, the metal gate structure 170 may not interface with bottom surfaces of the bottommost inner spacers 116.

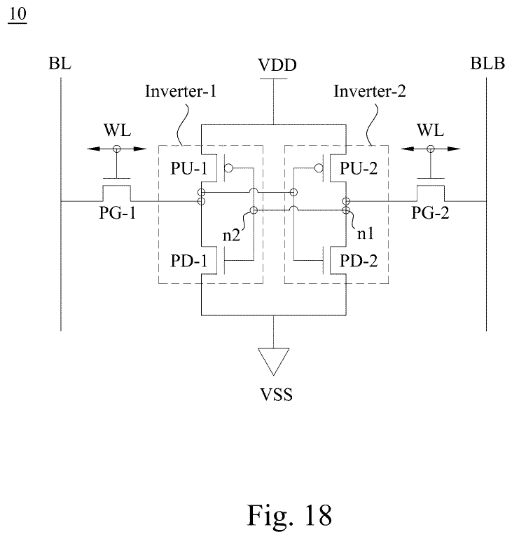

FIG. 18 illustrates a circuit diagram of a static random access memory (SRAM) cell, in accordance with some embodiments of the disclosure. A memory cell 10 is provided. The memory cell 10 may include a pair of cross-coupled inverters Inverter-1 and Inverter-2 and two pass-gate transistors PG-1 and PG-2. The inventers Inventer-1 and Inventer-2 are cross-coupled between the nodes n1 and n2, and form a latch circuit. In some embodiments, one of the nodes n1 and n2 is used as an output terminal of the latch circuit and the other node is used as in input terminal of the latch circuit. The pass-gate transistor PG-1 is coupled between a bit line BL and the node n2, and the pass-gate transistor PG-2 is coupled between a complementary bit line BLB and the node n1, wherein the complementary bit line BLB is complementary to the bit line BL. The gates of the pass-gate transistors PG-1 and PG-2 are coupled to the same word line WL. Furthermore, in some embodiments, the pass-gate transistors PG-1 and PG-2 are NMOS transistors. In some embodiments, the memory cell 10 may include two isolation transistors, wherein the sources of the isolation transistors are floating and the gates and the drains of one of the isolation transistors are coupled to one of the nodes n1 and n2. In some embodiments, the isolation transistors may be PMOS transistors.

The inverter Inverter-1 includes a pull-up transistor PU-1 and a pull-down transistor PD-1. The pull-up transistor PU-1 may be a PMOS transistor, and the pull-down transistor PD-1 may be an NMOS transistor. The drain of the pull-up transistor PU-1 and the drain of the pull-down transistor PD-1 are coupled to the node n2 connecting the pass-gate transistor PG1. The gates of the pull-up transistor PU-1 and the pull-down transistor PD1 are couple to the node n1 connecting the pass-gate transistor PG-2. Furthermore, the source of the pull-up transistor PU-1 is coupled to the power supply VDD, and the source of the pull-down transistor PD-1 is coupled to a ground VSS.

Similarly, the inverter Inverter-2 includes a pull-up transistor PU-2 and a pull-down transistor PD-2. The pull-up transistor PU-2 may be a PMOS transistor, and the pull-down transistor PD-2 may be a NMOS transistor. The drains of the pull-up transistor PU-2 and the pull-down transistor PD-2 are coupled to the node n1 connecting the pass-gate transistor PG-2. The gates of the pull-up transistor PU-2 and the pull-down transistor PD-2 are coupled to the node n1 connecting the pass-gate transistor PG-1. Furthermore, the source of the pull-up transistor PU-2 is coupled to the power supply VDD, and the source of the pull-down transistor PD-2 is coupled to the ground VSS.

In some embodiments that the memory cell 10 includes two isolation transistors, the drain and the gate of one of the isolation transistors are both coupled to the node n2 and the drain and the gate of another one of the isolation transistors are both coupled to the node n1. The sources of the isolation transistors are depicted as flowing. In some embodiments, the sources of the isolation transistors may be coupled to respective transistors in adjacent memory cells.

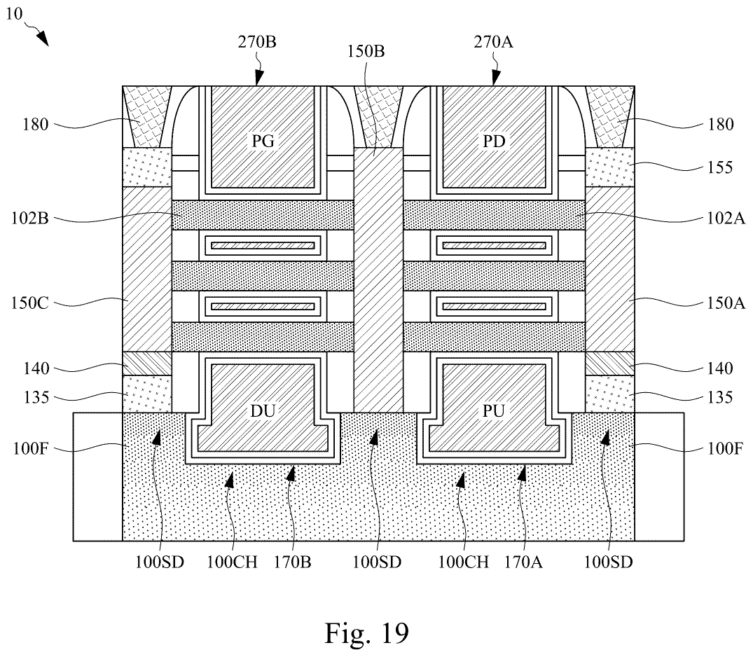

FIG. 19 is a cross-sectional view of a semiconductor device in accordance with some embodiments of the present disclosure. In greater detail, FIG. 19 is an example structure of the memory cell 10 as discussed in FIG. 18. Shown there is a substrate 100 having a semiconductor fin 100F. The memory cell 10 includes a pull-down transistor PD, a pull-up transistor PU, a pass-gate transistor PG, and a dummy transistor DU over the substrate 100. Here, the pull-down transistor PD, the pull-up transistor PU, the pass-gate transistor PG may be the pull-down transistor PD-1, the pull-up transistor PU-1, and the pass-gate transistor PG-1 as discussed in FIG. 18, respectively. Alternatively, the pull-down transistor PD, the pull-up transistor PU, the pass-gate transistor PG may be the pull-down transistor PD-2, the pull-up transistor PU-2, and the pass-gate transistor PG-2 as discussed in FIG. 18, respectively. Although present in the structure of FIG. 19, the dummy transistor DU does not function as a part of the memory cell 10.

In some embodiments, the pull-down transistor PD and the pass-gate transistor PG may include a similar configuration as the second transistor as discussed above with respect to FIGS. 1A to 16E. For example, the pull-down transistor PD may include semiconductor layers 102A, a metal gate structure 270A wrapping around each of the semiconductor layers 102A, and source/drain epitaxy structures 150A and 150B on opposite ends of the semiconductor layers 102A. Similarly, the pass-gate transistor PG may include semiconductor layers 102B, a metal gate structure 270B wrapping around each of the semiconductor layers 102B, and source/drain epitaxy structures 150B and 150C on opposite ends of the semiconductor layers 102B. In some embodiments, the pull-down transistor PD and the pass-gate transistor PG may share a common source/drain epitaxy structure 150B.

In some embodiments, the pull-up transistor PU and the dummy transistor DU may include a similar configuration as the first transistor as discussed above with respect to FIGS. 1A to 16E. For example, the pull-up transistor PU may include a semiconductor fin 100F and a metal gate structure 170A crossing the semiconductor fin 100F, in which the semiconductor fin 100F includes a channel portion 100CH below the metal gate structure 170A and source/drain portions 100SD along sidewalls of the metal gate structure 170A. Similarly, the dummy transistor DU may include a semiconductor fin 100F and a metal gate structure 170B crossing the semiconductor fin 100F, in which the semiconductor fin 100F includes a channel portion 100CH below the metal gate structure 170B and source/drain portions 100SD along sidewalls of the metal gate structure 170B.

The memory cell 10 further includes source/drain electrodes 135 in contact with source/drain portions 100SD of the semiconductor fin 100F. The memory cell 10 further includes source/drain contacts 155 in contact with the source/drain epitaxy structures 150A, 150B, and 150C, respectively. The memory cell 10 further includes source/drain vias 180 in contact with the respective source/drain contacts 155.

In some embodiments, the source/drain electrode 135 that is electrically connected with the source/drain portion 100SD of the pull-up transistor PU may be electrically connected to a power supply VDD. The source/drain epitaxy structure 150A of the pull-down transistor PD may be electrically connected to a power supply VSS through the respective source/drain contact 155 and the source/drain via 180. The source/drain epitaxy structure 150C of the pass-gate transistor PG may be electrically connected to a bit line BL through the respective source/drain contact 155 and the source/drain via 180. The metal gate structure 270B of the pass-gate transistor PG may be electrically connected to a word line WL.

Embodiments of the present disclosure provide a 6T (six-transistors) SRAM device with CFET configuration. The CFET configuration allows the 6T SRAM device to have a 4T (four-transistors) footprint, which achieves 2 pFETs in the 6T SRAM without area increase. Such configuration may be beneficial to decrease the device area, and will be beneficial for device shrinkage.

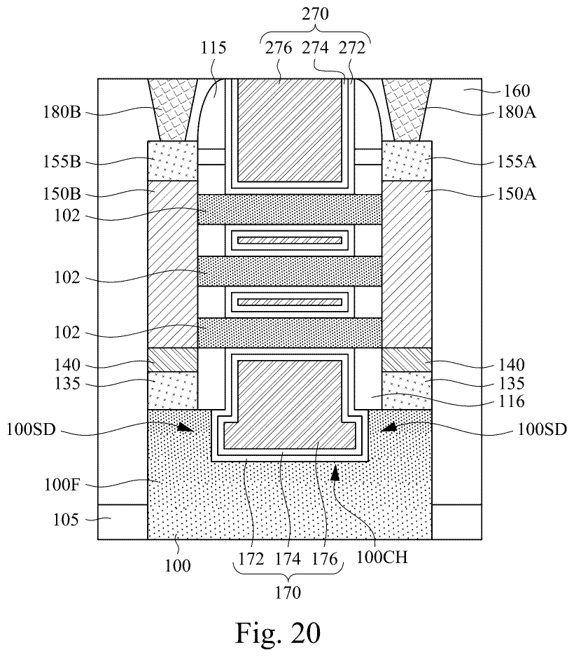

FIG. 20 is a cross-sectional view of a semiconductor device in accordance with some embodiments of the present disclosure. FIG. 20 is similar to FIG. 16B, and thus similar elements will be labeled the same, and relevant details will not be repeated for brevity. FIG. 20 is different from FIG. 16B, in that there is an additional source/drain electrode 135 and an additional isolation layer 140 between the source/drain epitaxy structure 150B and the semiconductor fin 100F. The additional source/drain electrode 135 and the additional isolation layer 140 can be formed together with the source/drain electrode 135 and the isolation layer 140 as discussed in FIGS. 8A to 9C. Accordingly, the source/drain epitaxy structure 150B may be separated from the semiconductor fin 100F. In such embodiments, the source/drain epitaxy structure 150B may include a similar configuration as the source/drain epitaxy structure 150A shown in the cross-sectional view of FIG. 16D.

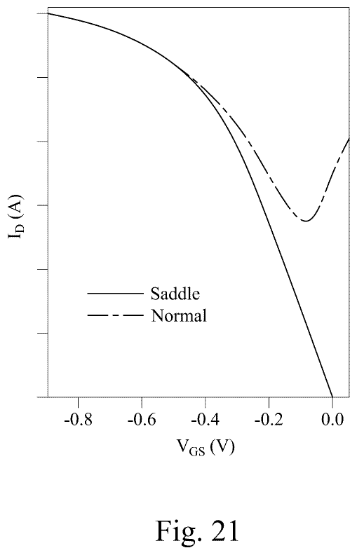

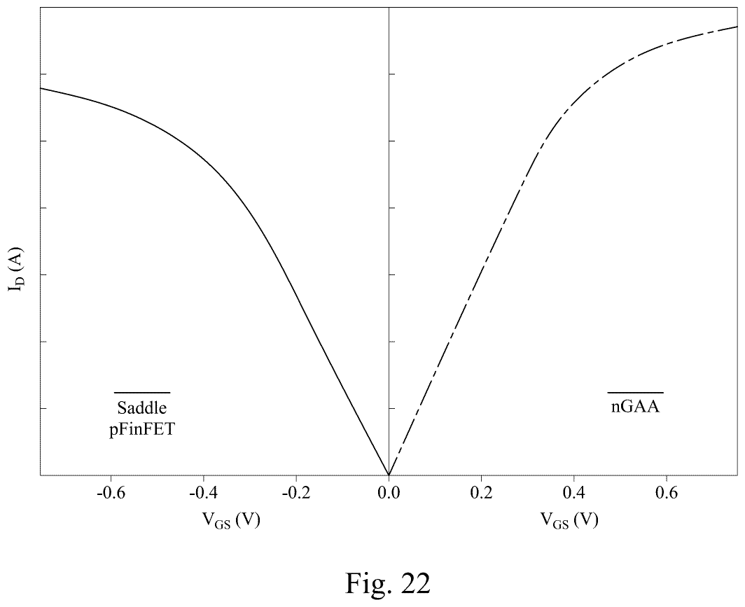

FIGS. 21 and 22 are simulation results of semiconductor devices in accordance with some embodiments of the present disclosure. FIG. 21 shows I-V curves of different p-type FinFET devices, in which a FinFET device with saddle-shape semiconductor fin and a FinFET device with a plan-top-surface semiconductor fin are simulated. The simulation results shows that FinFET device with a saddle-shape semiconductor fin include a stable I-V performance. However, current leakage may occur in the FinFET device with a plan-top-surface semiconductor fin when the gate-to-source (V_{GS}) is about 0.0 V to about −0.1V. FIG. 22 shows I-V curves of p-type FinFET device and an n-type GAA device, in which the p-type FinFET device includes a saddle-shape semiconductor fin. It can be seen that the p-type FinFET device includes a lower current than the n-type GAA device. This will also be beneficial for an SRAM device, since the n-type devices of the SRAM device is stronger than the p-type devices of the SRAM device.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method for forming a memory cell having a CFET configuration, in which the CFET device may include a bottom fin-type transistor and a top GAA transistor over the bottom Fin-type transistor. The CFET configuration may be beneficial for device shrinkage of the memory cell. The bottom fin-type transistor includes a gate structure crossing a semiconductor fin, in which the semiconductor fin may include a saddle-shape cross-sectional profile. This will result in that the channel portion of the semiconductor fin being at a lower position with lower dopant concentration than the source/drain portions of the semiconductor fin, which is beneficial to suppress current leakage, and thus the device performance will be improved.

In some embodiments of the present disclosure, a semiconductor device includes a substrate having a semiconductor fin, a first transistor over the substrate, and a second transistor vertically above the first transistor. The first transistor includes a first gate structure over the semiconductor fin, in which in a cross-sectional view, the semiconductor fin comprises a channel portion in contact with a bottom surface of the first gate structure, and source/drain portions on opposite sidewalls of the first gate structure. The second transistor includes a semiconductor channel layer above the semiconductor fin, a second gate structure over the semiconductor channel layer, and source/drain epitaxy structures on opposite ends of the semiconductor channel layer.

In some embodiments, the first gate structure is wider than the second gate structure in the cross-sectional view.

In some embodiments, the semiconductor device further includes an inner spacer between the semiconductor channel layer and the semiconductor fin, in which the first gate structure interfaces with a bottom surface of the inner spacer.

In some embodiments, each of the source/drain portions of the semiconductor fin has a dopant concentration that decreases downward from a top surface of the semiconductor fin.

In some embodiments, the semiconductor device further includes a source/drain electrode in contact with one of the source/drain portions of the semiconductor fin.

In some embodiments, the semiconductor device further includes an isolation layer vertically between the source/drain electrode and one of the source/drain epitaxy structures of the second transistor.

In some embodiments, the first transistor and the second transistor include opposite conductivity types.

In some embodiments, the first gate structure is in contact with the second gate structure.

In some embodiments of the present disclosure, a semiconductor device includes a substrate having a semiconductor fin, a first transistor over the substrate, a source/drain electrode, and a second transistor vertically above the first transistor. The first transistor includes a first gate structure having a portion embedded in the semiconductor fin. The source/drain electrode crosses a portion of the semiconductor fin. The second transistor includes a semiconductor channel layer above the semiconductor fin, a second gate structure over the semiconductor channel layer, and source/drain epitaxy structures on opposite ends of the semiconductor channel layer.

In some embodiments, a source/drain portion of the semiconductor fin in contact with a sidewall of the first gate structure has a gradient dopant concentration.

In some embodiments, the semiconductor fin comprises a source/drain portion of the semiconductor fin in contact with a sidewall of the first gate structure and a channel portion in contact with a bottom surface of the first gate structure, and wherein a maximum dopant concentration of the source/drain portion of the semiconductor fin is greater than a maximum dopant concentration of the channel portion of the semiconductor fin.

In some embodiments, the first gate structure is wider than the second gate structure.

In some embodiments, the semiconductor device further includes an isolation layer over the source/drain electrode.

In some embodiments, one of the source/drain epitaxy structures is in contact with the semiconductor fin, and another one of the source/drain epitaxy structures is spaced apart from the semiconductor fin.

In some embodiments, dopants of the semiconductor fin and dopants of the source/drain epitaxy structures have opposite conductivity types.

In some embodiments of the present disclosure, a method includes forming a stack of alternating sacrificial layers and semiconductor layers over a semiconductor fin; forming source/drain epitaxy structures on opposite ends of the semiconductor layers; performing an etching removing the sacrificial layers and a portion of the semiconductor fin, such that the semiconductor layers are suspended over the semiconductor fin and a recess is formed in the semiconductor fin; and forming a gate material wrapping around the semiconductor layers and in the recess of the semiconductor fin.

In some embodiments, forming the stack of the sacrificial layers and the semiconductor layers comprises forming a bottommost one of the sacrificial layers over the semiconductor fin, wherein the bottommost one of the sacrificial layers is doped; performing an annealing process to drive dopants of the bottommost one of the sacrificial layers into the semiconductor fin, such that the semiconductor fin has a gradient dopant concentration; and forming the semiconductor layers and other sacrificial layers over the bottommost one of the sacrificial layers after the annealing process is complete.

In some embodiments, the other sacrificial layers are un-doped.

In some embodiments, the method further includes forming a metal layer crossing a portion of the semiconductor fin prior to forming the source/drain epitaxy structures.

In some embodiments, the method further includes forming an isolation layer covering the metal layer, wherein the metal layer is spaced apart from one of the source/drain epitaxy structures through the isolation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate having a semiconductor fin;
a first transistor over the substrate and comprising a first gate structure over the semiconductor fin, wherein in a cross-sectional view, the semiconductor fin comprises a channel portion in contact with a bottom surface of the first gate structure, and source/drain portions on opposite sidewalls of the first gate structure; and
a second transistor vertically above the first transistor and comprising:
a semiconductor channel layer above the semiconductor fin;
a second gate structure over the semiconductor channel layer; and
source/drain epitaxy structures on opposite ends of the semiconductor channel layer.

2. The semiconductor device of claim 1, wherein the first gate structure is wider than the second gate structure in the cross-sectional view.

3. The semiconductor device of claim 1, further comprising an inner spacer between the semiconductor channel layer and the semiconductor fin, wherein the first gate structure interfaces with a bottom surface of the inner spacer.

4. The semiconductor device of claim 1, wherein each of the source/drain portions of the semiconductor fin has a dopant concentration that decreases downward from a top surface of the semiconductor fin.

5. The semiconductor device of claim 1, further comprising a source/drain electrode in contact with one of the source/drain portions of the semiconductor fin.

6. The semiconductor device of claim 5, further comprising an isolation layer vertically between the source/drain electrode and one of the source/drain epitaxy structures of the second transistor.

7. The semiconductor device of claim 1, wherein the first transistor and the second transistor include opposite conductivity types.

8. The semiconductor device of claim 1, wherein the first gate structure is in contact with the second gate structure.

9. A semiconductor device, comprising:
a substrate having a semiconductor fin;
a first transistor over the substrate and comprising a first gate structure having a portion embedded in the semiconductor fin;
a source/drain electrode crossing a portion of the semiconductor fin; and
a second transistor vertically above the first transistor and comprising:
a semiconductor channel layer above the semiconductor fin;
a second gate structure over the semiconductor channel layer; and
source/drain epitaxy structures on opposite ends of the semiconductor channel layer.

10. The semiconductor device of claim 9, wherein a source/drain portion of the semiconductor fin in contact with a sidewall of the first gate structure has a gradient dopant concentration.

11. The semiconductor device of claim 9, wherein the semiconductor fin comprises a source/drain portion of the semiconductor fin in contact with a sidewall of the first gate structure and a channel portion in contact with a bottom surface of the first gate structure, and wherein a maximum dopant concentration of the source/drain portion of the semiconductor fin is greater than a maximum dopant concentration of the channel portion of the semiconductor fin.

12. The semiconductor device of claim 9, wherein the first gate structure is wider than the second gate structure.

13. The semiconductor device of claim 9, further comprising an isolation layer over the source/drain electrode.

14. The semiconductor device of claim 9, wherein one of the source/drain epitaxy structures is in contact with the semiconductor fin, and another one of the source/drain epitaxy structures is spaced apart from the semiconductor fin.

15. The semiconductor device of claim 9, wherein dopants of the semiconductor fin and dopants of the source/drain epitaxy structures have opposite conductivity types.

16. A method, comprising:
forming a stack of alternating sacrificial layers and semiconductor layers over a semiconductor fin;
forming source/drain epitaxy structures on opposite ends of the semiconductor layers;
performing an etching removing the sacrificial layers and a portion of the semiconductor fin, such that the semiconductor layers are suspended over the semiconductor fin and a recess is formed in the semiconductor fin; and
forming a gate material wrapping around the semiconductor layers and in the recess of the semiconductor fin.

17. The method of claim 16, wherein forming the stack of the sacrificial layers and the semiconductor layers comprises:
forming a bottommost one of the sacrificial layers over the semiconductor fin, wherein the bottommost one of the sacrificial layers is doped;
performing an annealing process to drive dopants of the bottommost one of the sacrificial layers into the semiconductor fin, such that the semiconductor fin has a gradient dopant concentration; and
forming the semiconductor layers and other sacrificial layers over the bottommost one of the sacrificial layers after the annealing process is complete.

18. The method of claim 17, wherein the other sacrificial layers are un-doped.

19. The method of claim 16, further comprising forming a metal layer crossing a portion of the semiconductor fin prior to forming the source/drain epitaxy structures.

20. The method of claim 19, further comprising forming an isolation layer covering the metal layer, wherein the metal layer is spaced apart from one of the source/drain epitaxy structures through the isolation layer.
